(19) United States
(12) Patent Application Publication
(10) Pub. No.: US 2009/0057740 A1
(43) Pub. Date: Mar. 5, 2009

(54) Memory with surface strap

(75) Inventor: Wen-Yueh Jang, Hsinchu City (TW)

Correspondence Address: Joe McKinney Muncy, PO Box 1364, Fairfax, VA, 22038-1364, US

(73) Assignee: Winbond Electronics Corp.

(21) Appl. No.: 11/896,628

(22) Filed: Sep. 4, 2007

(51) Int. Cl. H01L 27/108; H01L 21/8242

(52) U.S. Cl. 257/301; 438/243; 257/E21.645; 257/E27.084

(57) ABSTRACT

A memory with a surface strap. The memory comprises a trench capacitor, a self-aligned surface strap and a MOS transistor. The trench capacitor is formed in a semiconductor substrate. The self-aligned surface strap covers an opening of the trench capacitor and a active region in the periphery thereof. One of the source/drain regions of the MOS transistor is connected to the surface strap and the other is connected to a bit line.

### BACKGROUND OF THE INVENTION

1. Field of the Invention

The invention relates to a memory and, in particular, to a dynamic random access memory (DRAM) with a surface strap.

2. Description of the Related Art

As semiconductor technology progresses below the 100 nm generation, device size scaling with technology becomes difficult, especially in a DRAM cell.

Table I is an international technological roadmap for semiconductors (ITRS). According to the ITRS roadmap, it is targeted to scale DRAM cell size from 8 F² to 6 F² in 2008.

TABLE I

| Year of Production | | | | | | | | |
|---|---|---|---|---|---|---|---|---|
| 2005 | 2006 | 2007 | 2008 | 2009 | 2010 | 2011 | 2012 | 2013 |
| DRAM ¼ Pitch (nm) (contacted) | | | | | | | | |
| 80 | 70 | 65 | 57 | 50 | 45 | 40 | 36 | 32 |

DRAM Product Table

| | | | | | | | | | |
|---|---|---|---|---|---|---|---|---|---|
| Cell area factor [a] | 8 | 8 | 8 | 6 | 6 | 6 | 6 | 6 | 6 |
| Cell area [Ca = af2] (mm²) | 0.051 | 0.041 | 0.032 | 0.019 | 0.015 | 0.012 | 0.0096 | 0.0077 | 0.0061 |
| Cell array area at production (% of | 63.00% | 63.00% | 63.00% | 56.08% | 56.08% | 56.08% | 56.08% | 56.08% | 56.08% |
| chip size) § | | | | | | | | | |
| Generation at production § | 1 G | 2 G | 2 G | 2 G | 4 G | 4 G | 4 G | 8 G | 8 G |
| Chip size at production (mm²) § | 88 | 139 | 110 | 74 | 117 | 83 | 74 | 117 | 93 |
| Gbits/cm2 at production § | 1.22 | 1.54 | 1.94 | 2.91 | 3.66 | 4.62 | 5.82 | 7.33 | 9.23 |

FIGS. 1A to 1L are schematic diagrams of a manufacturing process of a conventional DRAM cell with a buried strap. FIGS. 1A to 1G will be described in more detail in subsequent descriptions. FIG. 1G illustrates an unfinished trench capacitor. As shown in FIG. 1H, an N-type doped poly-silicon layer 310 fills the trench and is used as a top electrode of the trench capacitor. The N-type doped poly-silicon layer 310 is then etched back to a specific depth. Thereafter, the exposed collar oxide 320 is etched such that a top surface thereof is aligned with that of the doped poly-silicon, as shown in FIG. 1I. Subsequently, a buried strap silicon film 330 is filled in the trench, deposited on the doped poly-silicon layer 310 and the collar oxide 320, and etched back to a specific depth, as shown in FIG. 1J. In FIG. 1K, the buried strap film 330 is doped and the active area therein is patterned. Oxide is filled in to accomplish shallow trench isolation and planarization is accomplished by chemical mechanical polish. Ion implantation is performed and a gate dielectric layer, such as a oxide layer, is formed. A patterned poly-silicon and silicide layer is used as a gate layer. After formation of source/drain regions, a trench DRAM with a buried strap is finished, as shown in FIG. 1L. An insulating layer is typically formed between the buried strap and the trench such that dopant in the buried strap does not out-diffuse to the active area, resulting in punch-through of an access transistor. However, if the insulating layer is too thick, the trench capacitor is not electrically connected to the access transistor. As a result, the DRAM cell does not work. Accordingly, thickness of the insulating layer becomes a major challenge in process control.

### BRIEF SUMMARY OF THE INVENTION

An embodiment of a memory with a surface strap comprises a trench capacitor, a self-aligned surface strap and a MOS transistor. The trench capacitor is formed in a semiconductor substrate. The self-aligned surface strap covers an opening of the trench capacitor and an active region in the periphery thereof. One of the source/drain regions of the MOS transistor is connected to the surface strap and the other is connected to a bit line.

An embodiment of a manufacturing method of a memory with a surface strap comprises forming a patterned mask layer on a semiconductor substrate, forming a trench capacitor in the semiconductor substrate using the patterned mask layer, etching the patterned mask layer such that active area in the periphery of an opening of the trench capacitor is exposed, forming a self-aligned surface strap layer covering the trench capacitor and the active area in the periphery thereof, and forming a MOS transistor on the semiconductor substrate, wherein one of source/drain regions thereof is connected with the surface strap and the other is connected to a bit line.

The invention provides a memory with a surface strap and a manufacturing method thereof. According to the invention, DRAM cell size is scaled down to 6 F². In addition, no additional mask layer is required to form a surface strap due to self-aligned formation thereof.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1A to 1L are schematic diagrams of a manufacturing process of a conventional DRAM cell with a buried strap;

FIGS. 2B to 2G are schematic diagrams of a manufacturing process of a DRAM cell with a surface strap according to an embodiment of the invention;

FIG. 2A is a layout of trenches;

FIG. 2E-1 is a layout of active areas;

FIG. 2F-1 is a layout of a passing word line of an access transistor;

FIG. 3A is a layout of a word line of an access transistor of a memory with a self-aligned strap according to another embodiment of the invention;

FIGS. 3B and 3C are respectively cross sectional views along the lines A-A′ and B-B′ in FIG. 3A;

FIG. 4A is a layout of a word line of an access transistor of a memory with a self-aligned strap according to yet another embodiment of the invention; and

FIG. 4B is a cross sectional view along the line A-A′ in FIG. 4A.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

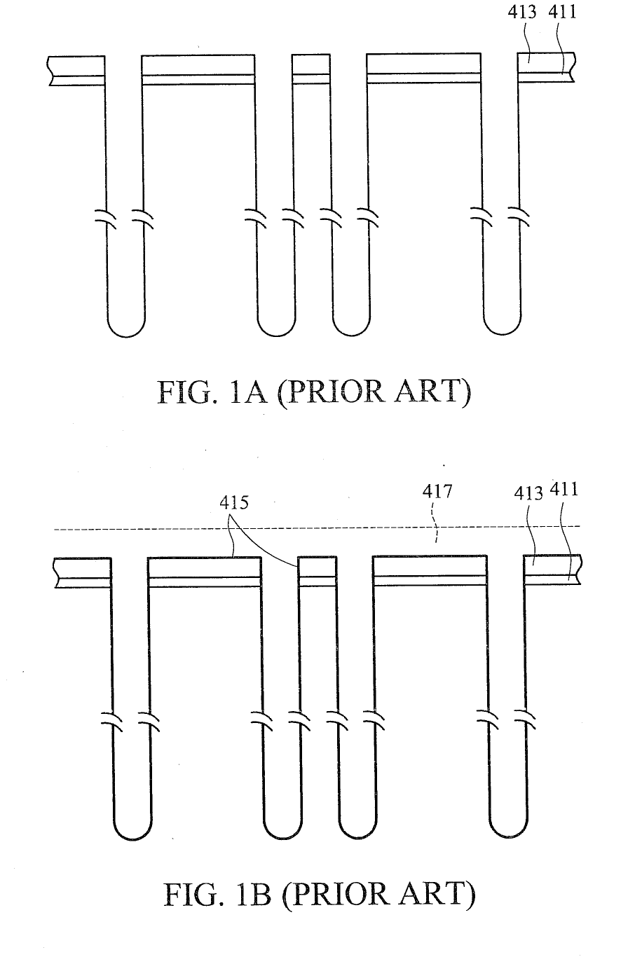

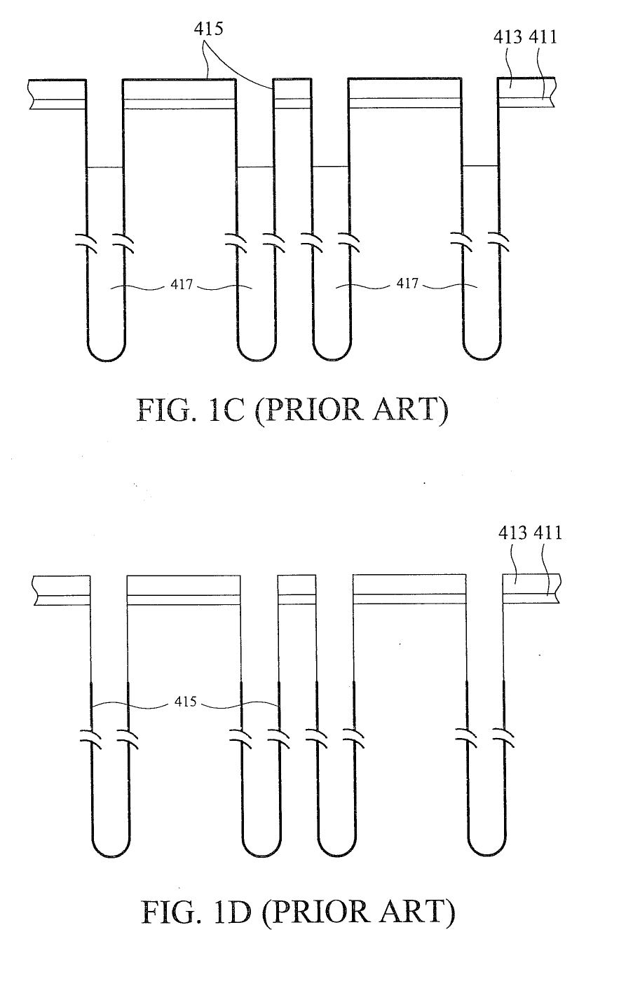

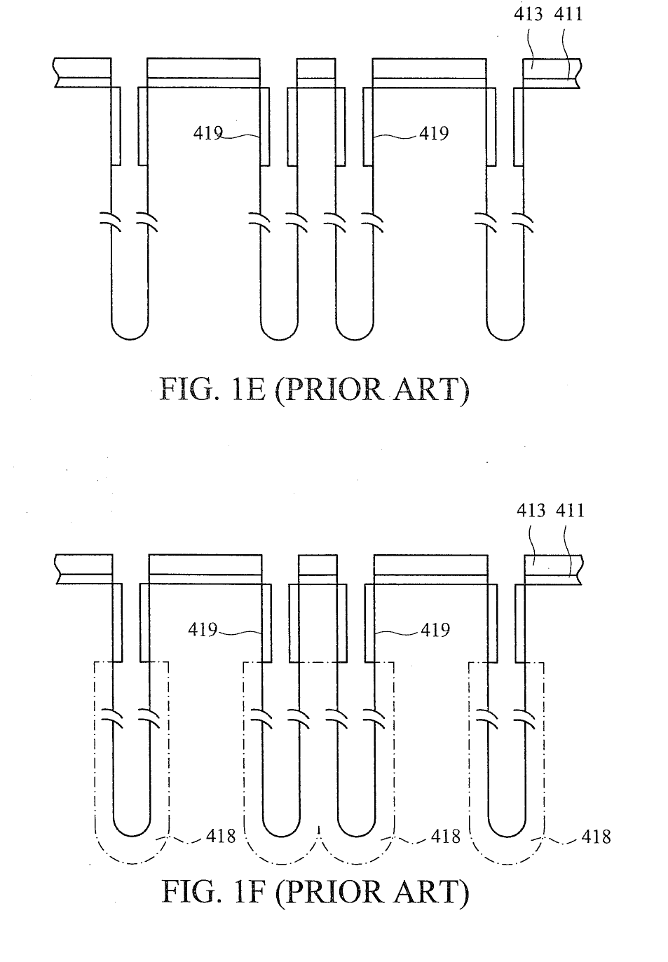

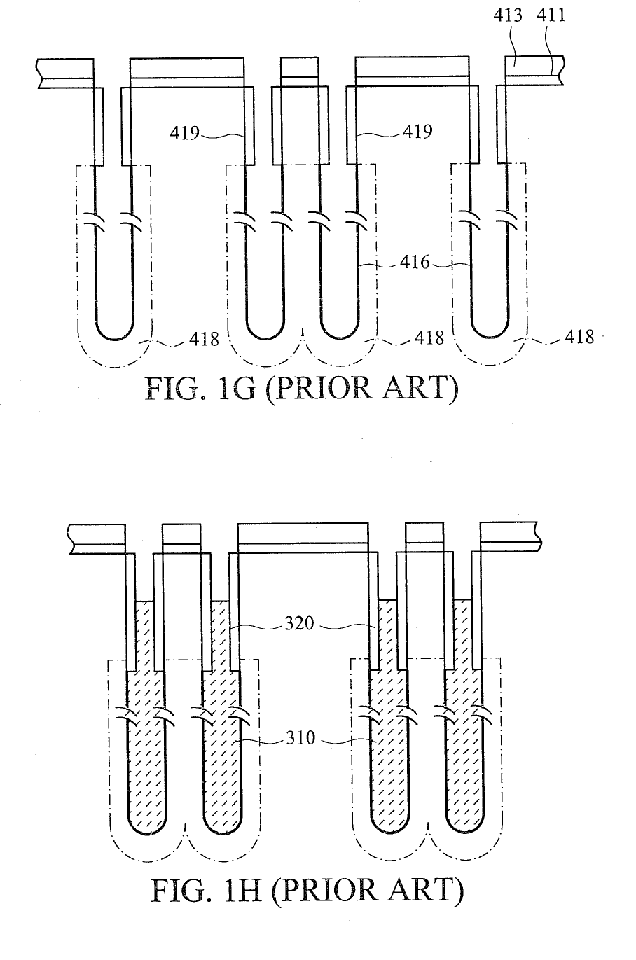

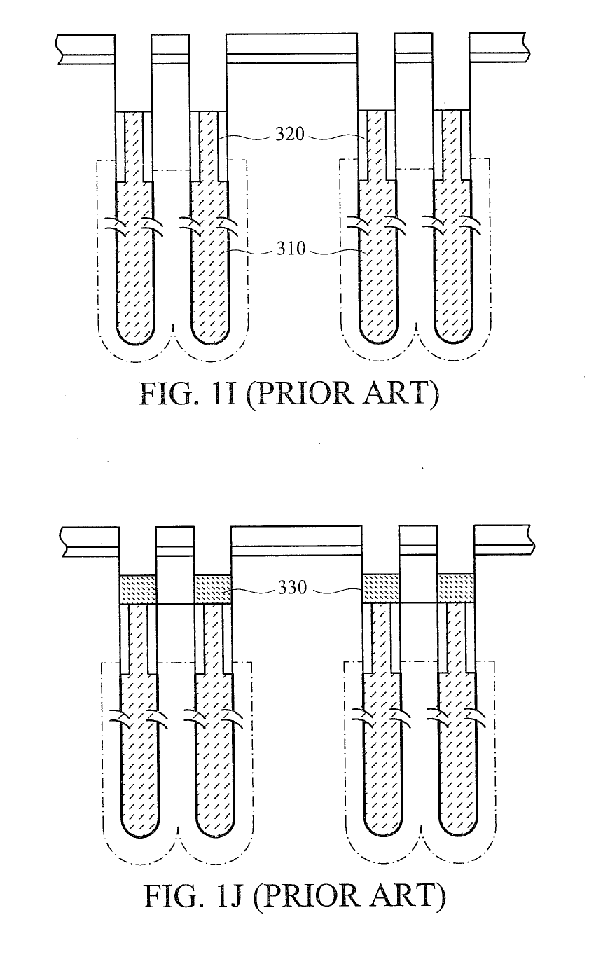

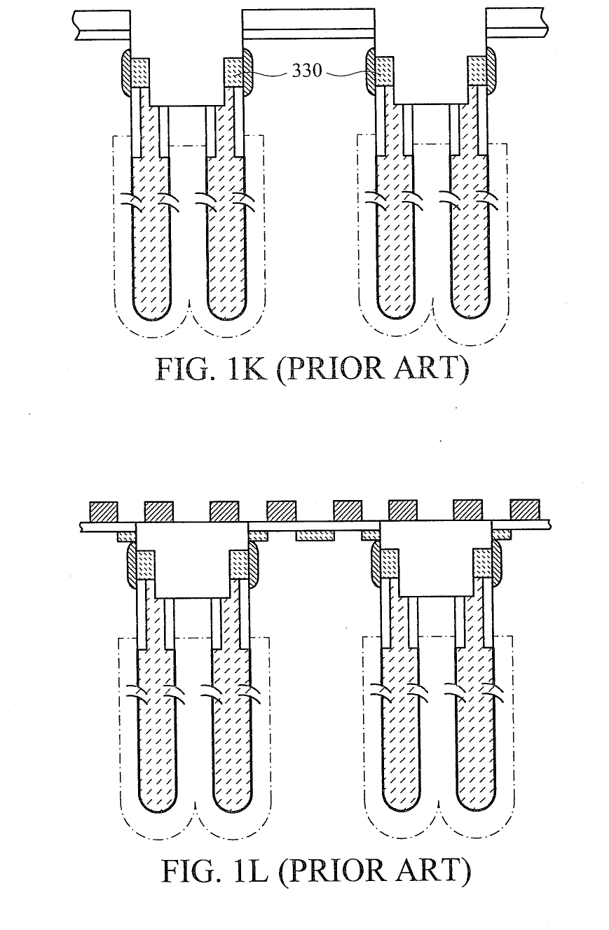

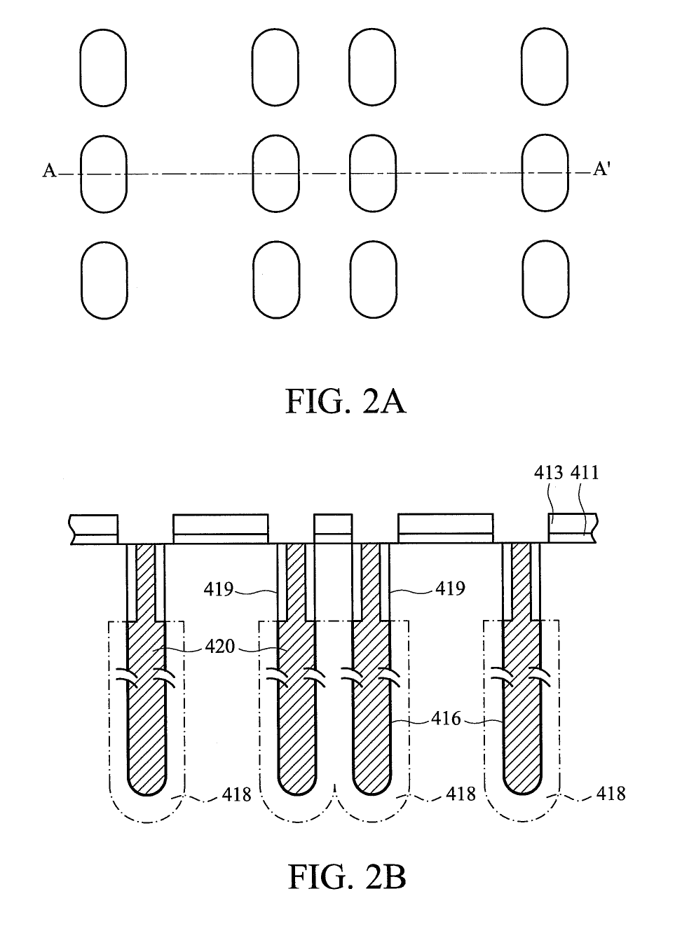

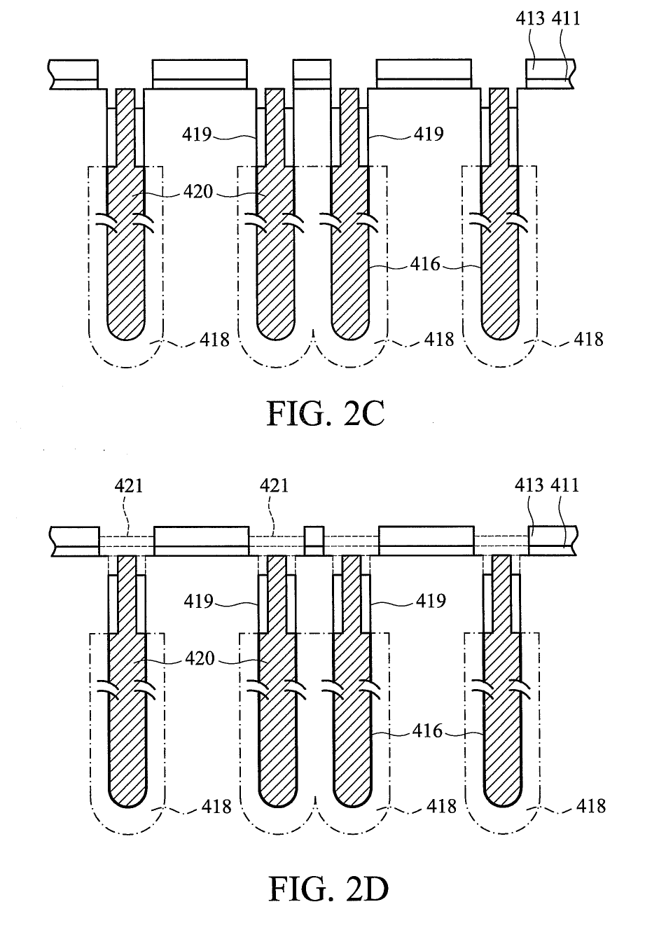

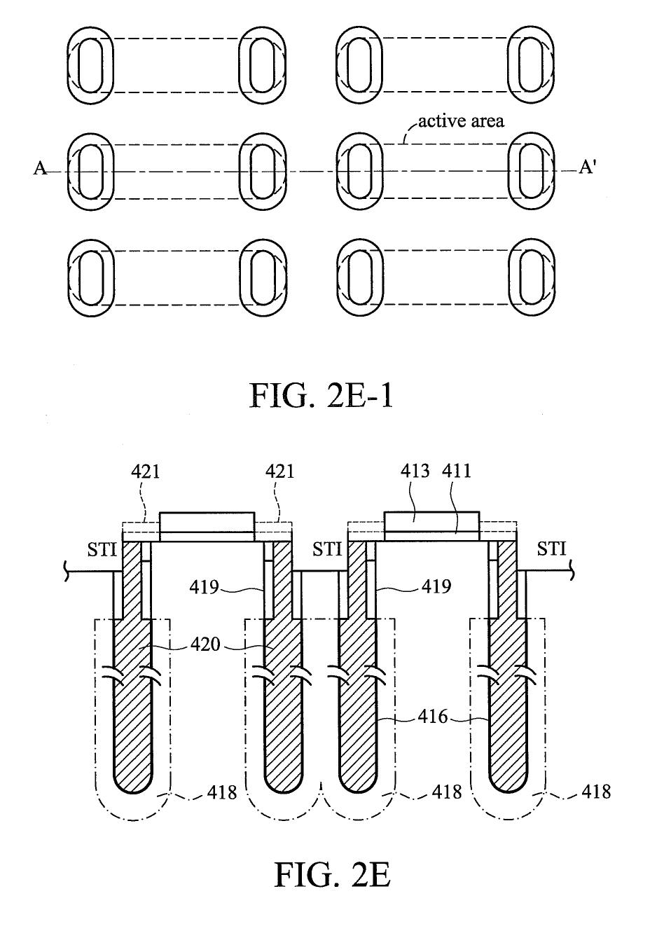

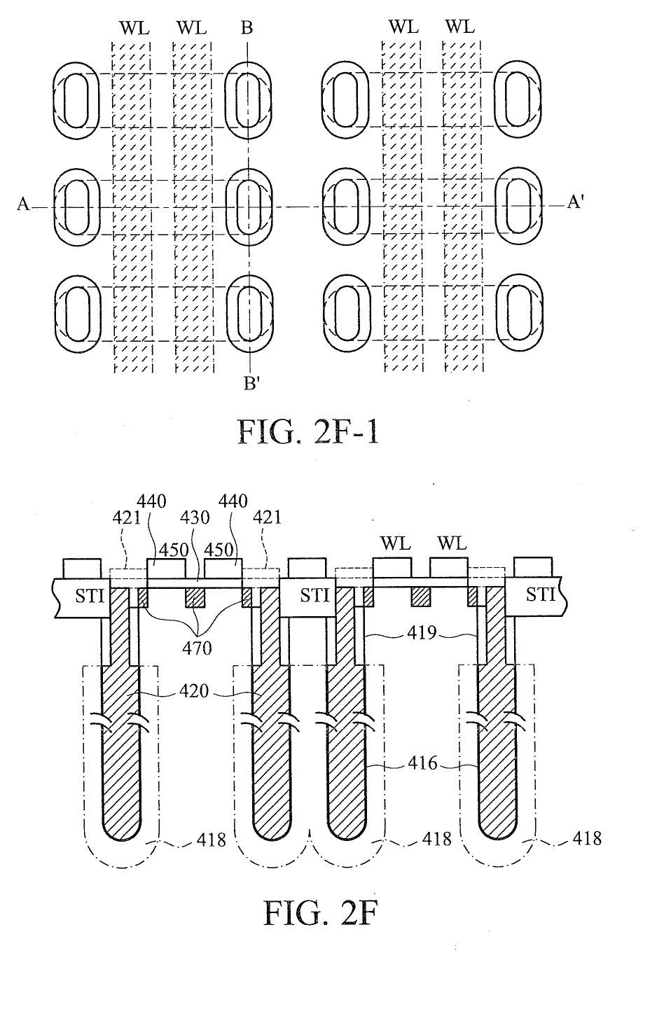

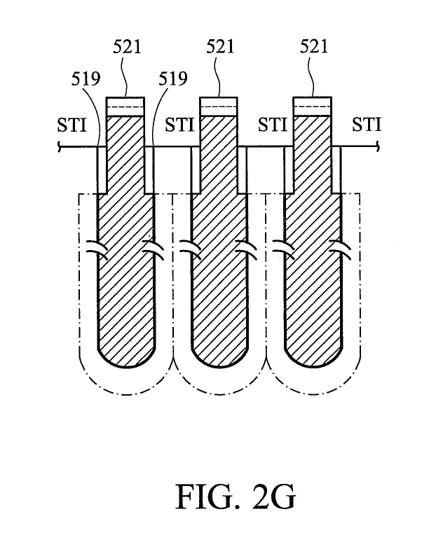

Front end processes of a memory with a surface strap according to an embodiment of the invention is the same as the conventional one shown in FIGS. 1A to 1G. An oxide layer (SiO₂) 411 and a nitride layer (Si₃N₄) 413 are sequentially formed on a P-type silicon substrate 410. The P-type silicon substrate 410 is etched according to the layout shown in FIG. 2A such that a trench as shown in FIG. 1A is formed. FIG. 1A is a cross sectional view along the line A-A′ in FIG. 2A. Subsequently, a nitride layer 415 is formed on the P-type silicon substrate 410 and the surface of the trench, as shown in FIG. 1B. In FIG. 1B, a sacrificial layer 417, typically a photo resist layer, is formed on the nitride layer. Then, the sacrificial layer 417 within a specific depth is removed, as shown in FIG. 1C. The exposed nitride layer 415 is subsequently removed and the sacrificial layer 417 is then completely removed, as shown in FIG. 1D. Thereafter, a collar oxide 419 is formed on the exposed surface of the trench and the nitride layer 415 is then completely removed, as shown in FIG. 1E. An N-type diffusion region 418, which is a bottom plate of the trench capacitor, is formed using thermal diffusion with N-type impurity gas to dope the trench surface, as shown in FIG. 1F. The trench surface covered by the collar oxide 419 is protected from doping. Thereafter, a dielectric layer 416, such as NO, is formed on the exposed trench surface, as shown in FIG. 1G. An N-type poly-silicon layer 420 is then deposited and filled in the trench to form a top plate of the trench capacitor, as shown in FIG. 2B. In FIG. 2B, the N-type poly-silicon layer 420 is etched back such that a top surface thereof is aligned with that of the P-type substrate 410. Thereafter, the collar oxide is etched to a depth of a source/drain junction of an access transistor, as shown in FIG. 1C. It is noted that etching of the collar oxide is optional. Then, the oxide layer (SiO₂) 411 and the nitride layer (Si₃N₄) 413 is etched such that the active area in the periphery of an opening of the trench capacitor is exposed, as shown in FIG. 2D. A surface strap silicon film 421 is then deposited on the P-type substrate 410 and etched back to a specific depth, which is at least lower than the top surface of the nitride layer (Si₃N₄) 413. As a result, a self-aligned surface strap is formed. Subsequently, the active area is patterned according to the layout shown in FIG. 2E-1. FIG. 2E is a cross sectional view along the line A-A′ in FIG. 2E-1. After patterning of the active area, oxide is filled in to accomplish shallow trench isolation and planarization is accomplished by chemical mechanical polish. Ion implantation is performed and a gate dielectric layer, such as an oxide layer, is formed. A poly-silicon and silicide layer is then deposited and patterned according to the layout in FIG. 2F-1 to form a gate layer. After formation of source/drain regions, a trench DRAM with a buried strap is finished, as shown in FIG. 2F. FIG. 2F is a cross sectional view along the line in FIG. 2F-1. It is noted that formation of the source drain regions of the access transistor can be realized by ion implantation or thermal diffusion of the dopant in the surface strap. FIG. 2G is a cross sectional view of the line B-B′ in FIG. 2F-1.

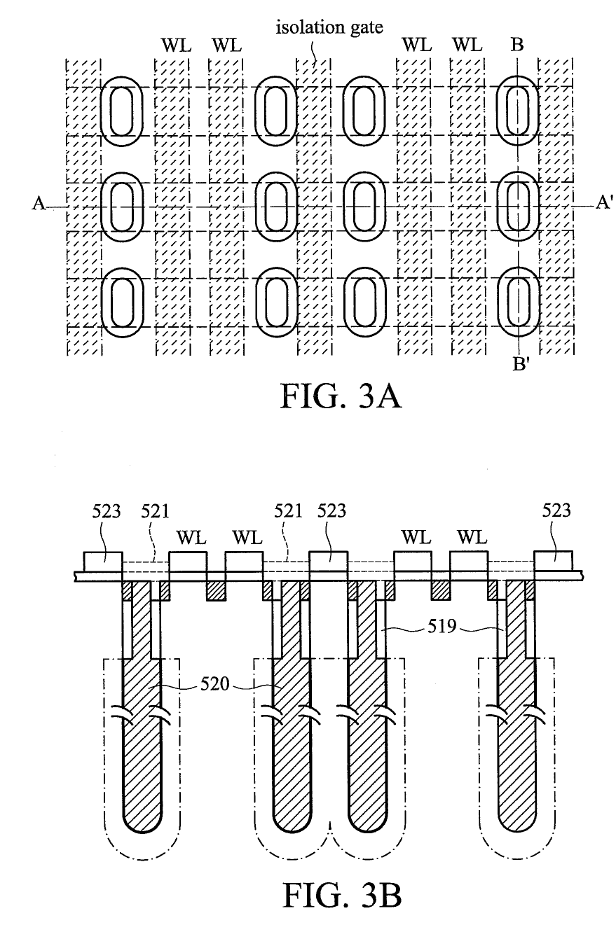

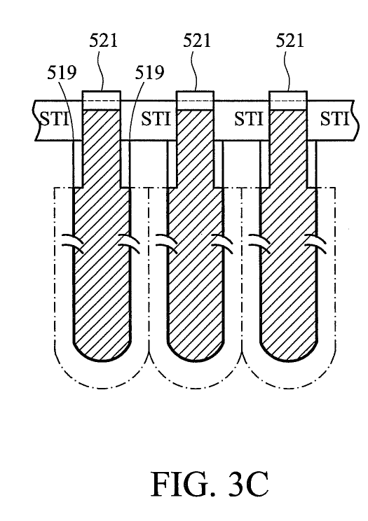

According to another embodiment of the invention, the layout in FIG. 2F-1 can be replaced by FIG. 3A. A final structure of the memory with a surface strap is shown in FIGS. 3B and 3C. FIGS. 3B and 3C are cross sectional views along the lines A-A′ and B-B′ of FIG. 3A, respectively. In FIGS. 3B and 3C, 521 is a surface strap layer and 523 an insulating gate.

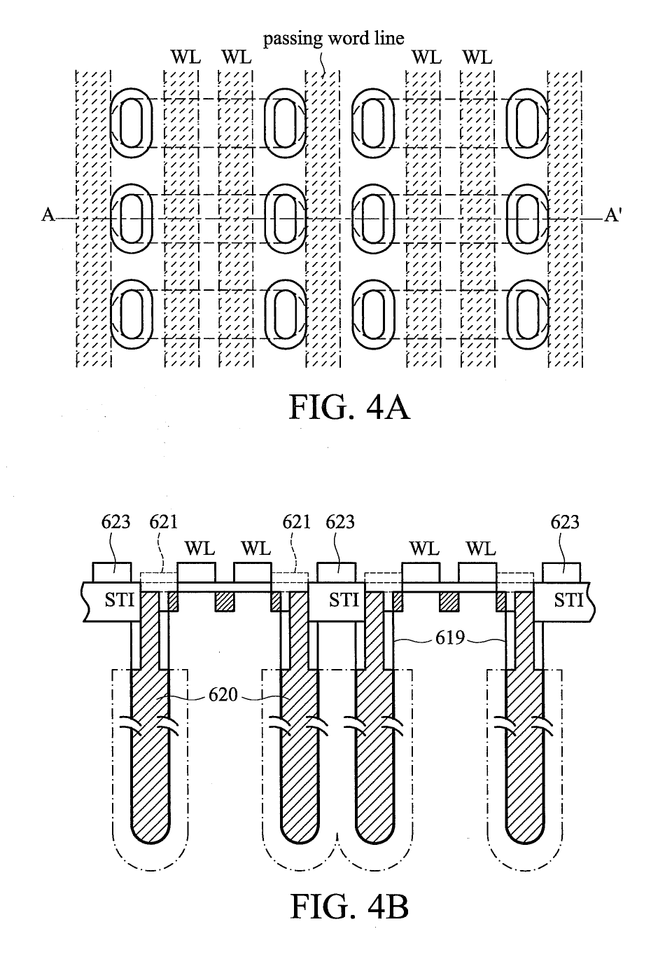

Additionally, according to yet another embodiment of the invention, the layout in FIG. 2F-1 can be replaced by FIG. 4A. A final structure of the memory with a surface strap is shown in FIG. 4B. FIG. 4B is a cross sectional view along the line A-A′ of FIG. 4A. In FIG. 4B, 621 is a surface strap layer and 623 a passing word line.

The invention provides a memory with a surface strap and a manufacturing method thereof. According to the invention, DRAM cell size is scaled down to 6 F². In addition, no additional mask layer is required to form a surface strap due to self-aligned formation thereof.

While the invention has been described by way of example and in terms of preferred embodiment, it is to be understood that the invention is not limited thereto. To the contrary, it is intended to cover various modifications and similar arrangements as would be apparent to those skilled in the Art. Therefore, the scope of the appended claims should be accorded the broadest interpretation so as to encompass all such modifications and similar arrangements.

1. A memory with a surface strap, comprising:
a trench capacitor formed in a semiconductor substrate;
a self-aligned surface strap covering an opening of the trench capacitor and an active region in the periphery thereof; and
a transistor with an upper surface of source/drain regions thereof in direct contact with the surface strap.

2. The memory with a surface strap as claimed in claim 1, wherein part of the self-aligned surface strap extends to the trench capacitor, and an extension depth thereof substantially equals that of the source/drain regions.

3. The memory with a surface strap as claimed in claim 1, wherein the trench capacitor comprises a bottomed plate formed with a trench surface of the semiconductor substrate, a dielectric layer attached to the trench surface of the semiconductor substrate, and a top plate filling the trench of the semiconductor substrate.

4. The memory with a surface strap as claimed in claim 3, wherein the bottom plate in an N-type diffusion region, and the top plate is doped poly-silicon.

5. The memory with a surface strap as claimed in claim 4, wherein the trench capacitor further comprises a collar oxide surrounding the top plate and a bottom edge thereof is aligned with an edge of the bottom plate.

6. A manufacturing method of a memory with a surface strap, comprising:
forming a patterned mask layer on a semiconductor substrate;
forming a trench capacitor in the semiconductor substrate using the patterned mask layer;
forming a self-aligned surface strap layer covering the trench capacitor and the active area in the periphery thereof; and
forming a MOS transistor on the semiconductor substrate, wherein one of source/drain regions thereof is connected with the surface strap and the other connected to a bit line.

7. The manufacturing method of a memory with a surface strap as claimed in claim 6, further comprising etching the patterned mask layer such that the active area in the periphery of an opening of the trench capacitor is exposed, and depositing and etching a surface strap film to a specific depth.

8. The manufacturing method of a memory with a surface strap as claimed in claim 7, wherein the step of forming the MOS transistor comprises out-diffusion of the dopant in the surface strap by thermal diffusion to form one of the source/drain regions.

9. The manufacturing method of a memory with a surface strap as claimed in claim 7, wherein the step of forming the MOS transistor comprises forming the source/drain regions by ion implantation.
